(19) United States
(12) Patent Application Publication
(10) Pub. No.: US 2024/0337018 A1
(43) Pub. Date: Oct. 10, 2024

(54) CORROSION-RESISTANT COATINGS AND METHODS OF PRODUCING SAME

(71) Applicant: Eugenus, Inc., San Jose, CA (US)

(72) Inventors: Mats Ingvar Larsson, Sunnyvale, CA (US); Selase Torkornoo, Sunnyvale, CA (US); Behzad Mahmoudi, San Jose, CA (US)

(21) Appl. No.: 18/625,614

(22) Filed: Apr. 3, 2024

Related U.S. Application Data
(60) Provisional application No. 63/494,629, filed on Apr. 6, 2023.

(51) Int. Cl. C23C 16/44; C09D 1/00; C09D 5/08; C23C 16/455

(52) U.S. Cl. CPC C23C 16/4404; C09D 1/00; C09D 5/084; C23C 16/45544

(57) ABSTRACT

A protective coating formed on a reaction chamber wall comprises a base layer comprising an oxide represented by a chemical formula of AₓB_{y}O_{z}, wherein A is a metal element, B is a metal or semiconductor element different from A, O is oxygen and each of x, y and z is >0. The protective coating is configured such that upon exposure to a fluorine (F)-containing reactant, at least a portion of the base layer reacts with the fluorine F-containing reactant and is converted to a F-containing region comprising a solid fluoride of the A.

### CROSS REFERENCE TO RELATED APPLICATIONS

Any and all applications for which a foreign or domestic priority claim is identified in the Application Data Sheet as filed with the present application are hereby incorporated by reference under 37 CFR 1.57. This application claims the benefit of U.S. Provisional Patent Application No. 63/494,629, filed Apr. 6, 2023, entitled “CORROSION-RESISTANT COATINGS AND METHODS OF PRODUCING SAME,” which is incorporated herein by reference in its entirety.

### BACKGROUND

### Field

The disclosed technology generally relates to forming protective coatings, and more particularly to corrosion resistant coating for the protection of surfaces of vapor deposition reaction chambers.

### Description of the Related Art

Vapor deposition systems are widely used within the semiconductor industry. These systems can efficiently and effectively deposit thin films through different deposition techniques, e.g., atomic layer deposition or other cyclic vapor depositions. Fluorine (F)-containing compounds are often used in vapor deposition systems, both as reactants and as cleaning agents. Some non-limiting examples of the usage of F-containing compounds include, to name a few: as a deposition precursor, e.g., in the form of a ternary halide; as an etchant for semiconductor surfaces, e.g., HF; and as a cleaning gas, e.g., hydrofluorocarbon compounds, NF₃ or F₂, to clean surfaces of reactor chambers and process equipment.

Because of fluorine's high reactivity, even otherwise corrosion resistant materials may be etched by fluorine. This unwanted corrosion by fluorine may limit the lifespan of reactor chambers as well as expensive showerheads and other process equipment.

As such, improved corrosion resistant coatings and methods for producing corrosion resistant coatings for vapor deposition systems would be advantageous.

### SUMMARY

In one aspect, a protective coating formed on a reaction chamber wall is disclosed. The protective coating comprises a base layer comprising an oxide represented by a chemical formula of AₓB_{y}O_{z}, wherein A is a metal element, B is a metal or semiconductor element different from the A, O is oxygen and each of x, y and z is greater than 0. The protective coating is configured such that upon exposure to a fluorine (F)-containing reactant, at least a portion of the base layer reacts with the fluorine F-containing reactant and is converted to a F-containing region comprising a solid fluoride of the A.

In some embodiment, a Pilling Bedworth ratio (R) of the A is between 0.5 and 2, wherein the R is defined as:

$$R = \frac{{n}_{1} {V}_{fluoride}}{{n}_{2} {V}_{oxide}}$$

Wherein n₁ and n₂ respectively represent numbers of moles of the A in the solid fluoride and the oxide in a balanced chemical reaction equation converting the oxide to the solid fluoride, and V_{fluoride} and V_{oxide} respectively represent volumes of the solid fluoride and the oxide. In some embodiment, the R of the element A is about 0.9 to 2.

In some embodiment, the A comprises one or more of aluminum (Al), hafnium (Hf), zirconium (Zr), calcium (Ca) and a rare earth element. In some embodiment, the base layer comprises one or more of HfSiO₄, ZrSiO₄, Al₂SiO₅, and CaCO₃. In some embodiment, the F-containing region has a chemical formula of AFₙ, wherein the A is the metal element, F is fluorine, and n>0. In some embodiment, the F-containing region comprises one or more of HfF₄, ZrF₄, CaF₂, and AlF₃.

In some embodiment, upon exposure to the fluorine-containing reactant, the at least a portion of the base layer reacts with the F-containing reactant and is converted to the F-containing region comprising the solid fluoride of the A and a volatile fluoride of the B. In some embodiment, upon exposure to the F-containing reactant, the at least a portion of the base layer reacts with the F-containing reactant and is converted to the F-containing region comprising the solid fluoride of the A and a volatile fluoride of the B in a chemical reaction accompanied by a negative change in free energy. In some embodiment, the volatile fluoride of the B has a chemical formula of BFₙ, where F is fluorine, and n>0. In some embodiment, the volatile fluoride of the B comprises one or more of SiF₄, CF₄ and GeF₄.

In some embodiment, a thickness of the F-containing region is greater than about 5 μm. In some embodiment, a thickness of the F-containing region is less than about 5 μm. In some embodiment, a thickness of the F-containing region is between about 1 μm and about 100 μm. In some embodiment, the F-containing reactant comprises HF, F₂, a fluorocarbon, a hydrofluorocarbon or combinations thereof. In some embodiment, the conversion of the base layer to the F-containing region stops when the F-containing region reaches a self-limiting thickness. In some embodiment, the self-limiting thickness is about 5 μm. In some embodiment, the protective coating is formed on the reaction chamber wall of a semiconductor processing chamber configured to flow a F-containing gas thereinto. In some embodiment, the semiconductor processing chamber has processed at least one semiconductor substrate, and wherein incorporation of at least some of F atoms of the F-containing region is caused by the processing of the at least one semiconductor substrate.

In another aspect, a semiconductor reaction chamber comprising the reaction chamber wall having the protective coating is disclosed. In some embodiment, the reaction chamber is an atomic layer deposition reaction chamber.

In another aspect, a protective coating formed on a reaction chamber wall is disclosed. The protective coating comprises a base layer comprising an oxide represented by a chemical formula of AₓB_{y}O_{z}, wherein A is a metal element, B is a metal or semiconductor element different from A, O is oxygen and each of x, y and z is >0. The protective coating additionally comprises a fluorine (F)-containing region comprising a solid fluoride of the A formed over the base layer.

In some embodiment, at least a portion of the base layer is configured to react with a F-containing reactant to form the F-containing region comprising the solid fluoride of the A upon exposure to the F-containing reactant. In some embodiment, the F-containing reactant comprises HF, F₂, a fluorocarbon, a hydrofluorocarbon or combinations thereof. In some embodiment, the exposure of the base layer to the F-containing reactant comprises removing the F-containing region above the base layer. In some embodiment, removing the F-containing region comprises scratching the F-containing region. In some embodiment, upon exposure to the F-containing reactant, the at least a portion of the base layer reacts with the F-containing reactant and is converted to the F-containing region comprising the solid fluoride of the A and a volatile fluoride of the B. In some embodiment, upon exposure to the F-containing reactant, the at least a portion of the base layer reacts with the F-containing reactant and is converted to the F-containing region comprising the solid fluoride of the A and a volatile fluoride of the B in a chemical reaction accompanied by a negative change in free energy. In some embodiment, the volatile fluoride of the B has a chemical formula of BFₙ, where F is fluorine, and n>0. In some embodiment, the volatile fluoride of the B comprises one or more of SiF₄, CF₄ and GeF₄. In some embodiment, the formation of the solid fluoride of the A stops when the F-containing region reaches a self-limiting thickness. In some embodiment, the self-limiting thickness is about 5 μm.

In some embodiment, a Pilling Bedworth ratio (R) of the A is between 0.5 and 2, wherein the R is defined as:

$$R = \frac{{n}_{1} {V}_{fluoride}}{{n}_{2} {V}_{oxide}}$$

wherein n₁ and n₂ respectively represent numbers of moles of the A in the solid fluoride and the oxide in a balanced chemical reaction equation converting the oxide to the solid fluoride, and V_{fluoride} and V_{oxide} respectively represent volumes of the solid fluoride and the oxide. In some embodiment, the R of the element A is about 0.9 to 2.

In some embodiment, the A comprises one or more of aluminum (Al), hafnium (Hf), zirconium (Zr), calcium (Ca) and a rare earth element. In some embodiment, the base layer comprises one or more of HfSiO₄, ZrSiO₄, Al₂SiO₅, and CaCO₄. In some embodiment, the F-containing region has a chemical formula of AFₙ, wherein the A is the metal, F is fluorine, and n>0. In some embodiment, the F-containing region comprises one or more of HfF₄, ZrF₄, CaF₂, and AlF₃. In some embodiment, a thickness of the F-containing region is greater than about 5 μm. In some embodiment, a thickness of the F-containing region is less than about 5 μm. In some embodiment, a thickness of the F-containing region is between about 1 μm and about 100 μm. In some embodiment, the protective coating is formed on the reaction chamber wall of a semiconductor processing chamber configured to flow a F-containing gas thereinto. In some embodiment, the semiconductor processing chamber has processed at least one semiconductor substrate, and wherein incorporation of at least some of F atoms of the F-containing region is caused by the processing of the at least one semiconductor substrate.

In another aspect, a semiconductor reaction chamber comprises the reaction chamber wall having the protective coating according to any one of the above aspects.

In another aspect, a method of forming a protective coating on a reaction chamber wall is disclosed. The method comprises providing a reaction chamber comprising the reaction chamber wall and forming thereon a base layer comprising an oxide represented by a chemical formula of AₓB_{y}O_{z}, wherein A is a metal element, B is a metal or semiconductor element different from A, O is oxygen and each of x, y and z is >0. The protective coating is configured such that upon exposure to a fluorine (F)-containing reactant, at least a portion of the base layer reacts with the F-containing reactant and is converted to a F-containing region comprising a solid fluoride of the A.

In some embodiment, the method further comprises exposing the base layer to the F-containing reactant, thereby converting at least the portion of the base layer to the F-containing region. In some embodiment, providing the base layer comprises lining the reaction chamber wall of a vapor deposition system with the base layer. In some embodiment, at least lining the reaction chamber wall occurs prior to a first use of the reaction chamber to process a semiconductor substrate. In some embodiment, exposing the base layer to the F-containing reactant occurs in situ during a vapor deposition process on a semiconductor substrate. In some embodiment, the F-containing reactant is a by-product of a vapor deposition process within the reaction chamber. In some embodiment, the F-containing reactant is not a by-product of a vapor deposition process within the reaction chamber.

### BRIEF DESCRIPTION OF THE DRAWINGS

These and other features, aspects, and advantages of the present disclosure are described with reference to the drawings of certain embodiments, which are intended to illustrate certain embodiments and not to limit the invention.

FIGS. 1A-1D illustrate a self-healing mechanism of the self-healing coating according to some embodiments.

FIGS. 2A-2C schematically illustrate the formation of surface layers according to different Pilling Bedworth ratio values.

FIG. 3 illustrates the formation energies of some fluorine-containing gases.

FIG. 4 graphically illustrates the free energy curves of fluorine-containing gases.

FIG. 5A illustrates the electronic structure of a self-healing layer material according to one embodiment.

FIG. 5B illustrates the crystalline structure of a self-healing layer material according to one embodiment.

FIG. 6 illustrates the surface reactions of self-healing coatings according to some embodiments.

FIG. 7 is a flow chart schematically illustrating a method of forming a self-healing protective bi-layer coating, according to some embodiments.

### DETAILED DESCRIPTION

As described above, there is a need in the semiconductor industry, and in particular in the context of vapor deposition systems, for corrosion resistant coatings. To address these and other needs, disclosed herein is a corrosion resistant self-healing coating comprising a base layer comprising an oxide having a general composition of AₓB_{y}O_{z}, wherein A is a first metal, B is a second element, O is oxygen, x is >0, y is >0, and z is >0. In some embodiments, the base layer of the self-healing coating can at least partially react with fluorine (F)-containing reactants to form a F-containing protective surface region or layer near the surface of the base layer having a general form of AFₙ, wherein A is the first metal and F is fluorine. In some embodiments, the AFₙ surface region or layer may be formed by a reaction between a fluorine-containing reactant and the base layer of the corrosion resistant self-healing layer. In some embodiments, the AFₙ surface region or layer may be configured to suppress fluorine (F) diffusion into the underlying coating layers. In some embodiments, the AFₙ surface region or layer may be polycrystalline. In some embodiments, a polycrystalline AFₙ surface region or layer may have relatively low density of grain boundaries so as to suppress F diffusion through the underlying interface.

In some embodiments, the self-healing coating may form a bi-layer coating when exposed to a fluorine containing gas. In some embodiments, the formation of a bi-layer coating comprises forming a AFₙ surface region or layer on the surface of the base layer. In some embodiments, the general chemical formula for the reaction that forms the AFₙ surface region or layer may be described by the following general chemical formula:

$${A}_{x} {B}_{y} {O}_{z} ( s ) + m {H}_{e} {F}_{g} ( g ) \to {xAF}_{n} ( s ) + {yBF}_{d} ( g ) + \frac{e}{2} H 2 O + \frac{( z - e )}{2} {O}_{2} ( g ) ,$$

where: A is a first metal; B is a second element; O is oxygen; F is fluorine; and each of x, y, z, m, n, d, and g can be a number >0, e.g., an integer >0; and e can be 0 or a number >1, e.g., an integer >0. The inventors have discovered that one advantageous aspect of this reaction synthesis is that the byproducts BF_{d} and O₂ (or H₂O) may form in the gaseous phase and may be easily removed from the reaction area after the formation of the AFₙ surface region or layer, which may form in the solid phase.

As described herein, a compound referred to by its constituent elements without specific stoichiometric ratios thereof shall be understood to encompass all possible nonzero concentrations of each element unless explicitly limited. For example, aluminum fluoride (AlF) shall be understood to encompass all possible stoichiometric and nonstoichiometric compositions of aluminum fluoride that can be expressed by a general formula AlFₙ, where n>0, including but not limited to AlF and AlF₃.

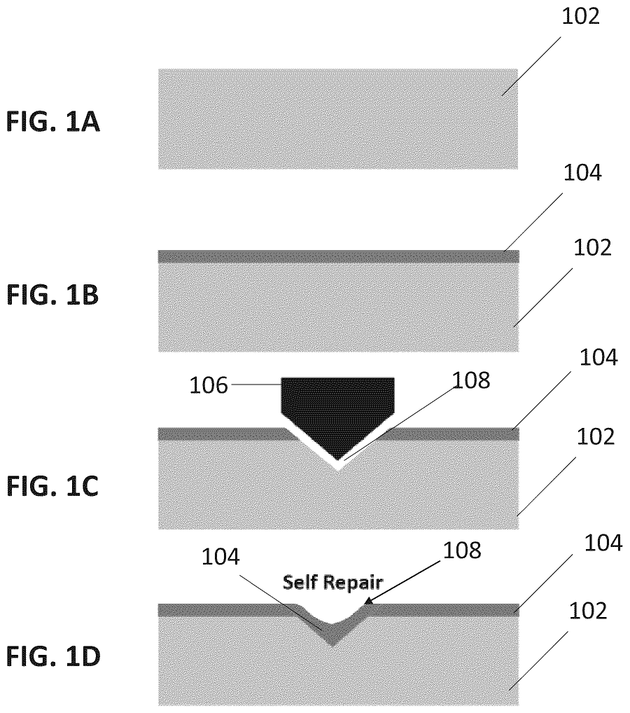

Without being bound to any theory or mechanism, FIGS. 1A-D illustrate an exemplary formation and self-healing mechanism of a self-healing coating according to some embodiments. In FIG. 1A, a protective coating 102, e.g., a base layer of a self-healing coating, having an oxide with a chemical formula of AₓB_{y}O_{z} is provided. In some embodiments, as illustrated in FIG. 1B, contacting the base layer of the self-healing coating 102 with a fluorine containing reactant may form a fluorine containing protective surface region or layer 104. The fluorine containing protective surface region or layer 104 may have a general chemical composition AFₙ. as described above. In some embodiments, the F-containing protective surface region or layer 104 may be polycrystalline. In some embodiments, the F-containing protective surface region or layer 104 may have a low density of grain boundaries sufficient to suppress diffusion of F to the underlying surface, e.g., the bulk of the base layer of the self-healing coating 102. In some embodiments, further exposure of F-containing protective surface region or layer 104 to a F-containing reactant may not form more F-containing protective surface region or layer 104, i.e., the formation of the F-containing protective surface region or layer 104 stops when the F-containing protective surface region or layer 104 reaches a certain thickness. In some embodiments, the F-containing protective region or layer 104 stops to grow when it reaches a self-limiting thickness of, of about, of at least about, of at most about 1 μm, 5 μm, 10 μm, 50 μm, 100 μm, or any value in a range defined by any these values. FIG. 1C schematically illustrates the mechanical damage that may occur to the F-containing protective surface region or layer 104 and self-healing coating 102 according to some embodiments. For instance, a mechanical instrument 106 may form a scratch 108 in the F-containing protective surface region or layer 104 and the base layer of the self-healing coating 102. In some embodiments, as illustrated in FIG. 1C, the scratch 108 may remove some of the F-containing protective surface region or layer 104 and the base layer of the self-healing coating 102, exposing a portion of the base layer of the self-healing coating 102. FIG. 1D illustrates the self-healing mechanism of the self-healing coating 102 according to some embodiments. After a portion of the base layer of the self-healing coating 102 is exposed, contacting the base layer of the self-healing coating 102 with a F-containing reactant can re-form the F-containing protective surface region or layer 104 in the exposed surface of the scratch 108. This self-repair mechanism may be suitable to protect the self-healing coating 102 from further fluorination when exposed to a F-containing reactant.

In some embodiments, the self-healing coating is formed on the interior surfaces of a vapor deposition system. In some embodiments, the interior surfaces of a vapor deposition system comprise all of the parts of the vapor deposition system, e.g., showerheads, reactor chambers, susceptors etc. In some embodiments, prior to the first use of the reactor a self-healing coating is formed on the reactor surfaces. In some embodiments, prior to a first deposition on a substrate, the self-healing coating is exposed to a F-containing reactant to form a F-containing protective surface region or layer.

In some embodiments, the base layer of the self-healing coating layer may be an oxide having the general formula of AₓB_{y}O_{z}, wherein A is a first metal element, B is a second metal or semiconductor element, O is oxygen, each of x, y and z is greater than zero, e.g., an integer. In some embodiments, the first metal A may be a rare earth metal. In some embodiments, the first metal A may be scandium (Sc), yttrium (Y), lanthanum (La), neodymium (Nd), hafnium (Hf) zirconium (Zr), calcium (Ca), any suitable metal in accordance with the inventive aspects disclosed herein, or combinations thereof. In some embodiments, the first metal A may be Al, Y, Zr, Hf, Ca, or combinations thereof. In some embodiments, the first metal A may be Al.

In some embodiments, the second element B may be a metal element. In some embodiments, the second element B is not a metal element. In some embodiments, the second element B is a semiconductor element. In some embodiments, the second element B may comprise carbon, germanium, selenium, silicon, sulfur, tellurium, nitrogen, or combinations thereof. In some embodiments, the second element B may be silicon, carbon, nitrogen, boron, phosphorus, or combinations thereof. In some embodiments, the second element B may be silicon (Si). The use of silicon as second element B may be advantageous due to silicon's advantageous effect on the Pilling Bedworth ratio of the system, as discussed below. In some embodiments, the second element B may be carbon (C). In some embodiments, the second element B may be germanium (Ge). In some embodiments, the second element B may be any suitable element for forming an oxide.

In some embodiments, the base layer of the self-healing coating may comprise HfSiO₄, ZrSiO₄, Al₂SiO₅, CaCO₃, any other suitable oxide in accordance with the inventive aspects disclosed herein, or combinations thereof. In some embodiments, the base layer of the self-healing coating comprises Al₂SiO₅.

In some embodiments, the F-containing protective surface layer 104 may be formed by contacting the base layer of the self-healing coating 102 with a F-containing reactant. In some embodiments, the general formula for the formation of the F-containing protective surface layer

$$104 {A}_{x} {B}_{y} {O}_{z} ( s ) + m {H}_{e} {F}_{g} ( g ) \to {xAF}_{n} ( s ) {yBF}_{d} ( g ) + \frac{e}{2} {H}_{2} O ( g ) + \frac{( z - e )}{2} {O}_{2} ( g ) ,$$

where: A is a first metal; B is a second element; O is oxygen; F is fluorine; and each of x, y, z, m, g, n, and d can be a number >0, e.g., an integer >0; and e can be 0 or a number, >1, and the F-containing protective surface layer is AFₙ(s). In some embodiments, the F-containing surface layer 104 may be AlF₃, ZrF₄, HfF₄, CaF₂, or any suitable F-containing layer. In some embodiments, AFₙ is amorphous. In some embodiments, the AFₙ is polycrystalline. In some embodiments, the polycrystalline AFₙ may allow grain boundary control to suppress F diffusion to the underlying base layer and substrate layer. In some embodiments, the BF_{d} comprises SiF₄, CF₄, GeF₄, or any suitable volatile fluoride, or combinations thereof.

In some embodiments, the F-containing protective surface layer 104 may be formed by contacting the self-healing coating 102 with a F-containing reactant. In some embodiment, the F-containing reactant comprises HF, F₂, fluorocarbon, hydrofluorocarbon, or combinations thereof. In some embodiments, the F-containing reactant can be HF. In some other embodiments, the F-containing reactant can be F₂. In some other embodiments, the F-containing reactant can be any reactive species containing fluorine, e.g., a fluorocarbon or a hydrofluorocarbon.

In some embodiments, the F-containing protective surface layer 104 may be formed by contacting the base layer of the self-healing coating 102 with a F-containing reactant. In some embodiments, the F-containing protective surface layer 104 has a thickness suitable to effectively suppress or stop the diffusion of F through the F-containing protective surface layer 104 to the base layer of the self-healing coating 102. In some embodiments the thickness of the F-containing protective surface layer 104 is at least about 1 μm, 5 μm, 10 μm, 50 μm, 100 μm or any value in a range defined by any these values. In some embodiments the thickness of the F-containing protective surface layer 104 is at most about 1 μm, 5 μm, 10 μm, 50 μm, 100 μm, or any value in a range defined by any of these values.

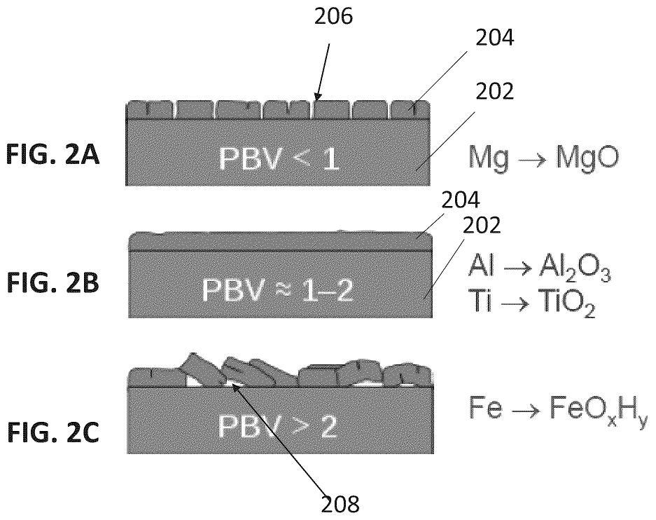

While different oxide systems are known with the general formula AₓB_{y}O_{z}, not all metal oxides are suitable materials for self-healing coatings. Many metal oxides react with fluorine to create non-stable layer coatings which do not protect underlying layers from further reaction with fluorine. These non-stable layer coatings are themselves prone to further corrosion and may themselves contaminant a deposition system. Without being bound to any theory, one possible reason for this is that the Pilling-Bedworth ratio of the metal fluoride top layer formed from the reaction between the metal oxide AₓB_{y}O_{z} and F-containing reactant may be either too large or too small. The Pilling-Bedworth ratio of metals here is defined as the ratio of the volume of the elementary cell of a metal-fluoride to the volume of the elementary cell of the corresponding metal oxide from which the metal fluoride is created. This relationship can be expressed by the following equation:

$$R = \frac{{n}_{1} {V}_{fluoride}}{{n}_{2} {V}_{oxide}}$$

Where R is the Pilling-Bedworth ratio of metal A in the metal oxide AₓB_{y}O_{z}, n₁ is the number of metal element A in the metal oxide and n₂ is the number of metal element A in the metal fluoride. The inventors have discovered that the self-healing coatings may be more effective when their Pilling Bedworth ratio is relatively close to 1, e.g., between 0.9 and 2 or between 1 and 2. FIGS. 2A-2C schematically illustrate the formation of surface layers according to different Pilling Bedworth ratio values. FIG. 2A illustrates a self-healing coating layer in which the Pilling Bedworth ratio is less than 1. When the Pilling Bedworth ratio is less than 1, then the F-containing protective surface layer 204 which may be formed on the base layer 202 may have gaps 206 in the F-containing protective surface layer 204. The gaps 206 may allow further fluorine to diffuse between the F-containing protective surface layer and react with the underlying base layer 202. Moreover, gaps 206 may cause the F-containing protective surface layer 204 to be mechanically and chemically unstable. This instability may lead to flaking from the F-containing protective surface layer 204. Flaking from the F-containing protective surface layer 204 can be disadvantageous in chemical deposition systems, because, as stated above, this flaking may cause for unwanted particles in a deposition system.

FIG. 2B illustrates a self-healing coating layer having a base layer 202 with a Pilling Bedworth ratio between about 1 and about 2, according to embodiments. When the Pilling Bedworth ratio is between about 1 and about 2, then the F-containing protective surface layer 204 will have few to no gaps 206. This substantially gapless layer may lead to better protection of the underlying base layer 202. Moreover, at Pilling Bedworth ratios of about 1 to about 2, there may be higher grain boundary control, e.g., fewer grain boundaries 208, in the F-containing protective surface layer 204. Fewer grain boundaries 208 may stop diffusion of F-containing species through the F-containing protective surface 204.

FIG. 2C illustrates a self-healing coating layer having a base layer 202 in which the Pilling Bedworth ratio is greater than 2. When the Pilling Bedworth ratio is greater than 2, then the F-containing protective surface layer 204 which may be formed on the base layer 202 may have many grain boundaries 208 in the F-containing protective surface layer 204. The grain boundaries 208 may allow fluorine to diffuse through the F-containing protective surface layer and react with the self-healing coating layer 202. Moreover, grain boundaries 208 may cause the F-containing protective surface layer 204 to be mechanically and chemically unstable. This instability may lead to the flaking from the F-containing protective surface layer 204. Flaking off of the F-containing protective surface layer 204 can be disadvantageous in chemical deposition systems, because, as stated above, this flaking may cause for unwanted particles in a deposition system.

In some embodiments, the base layer of the self-healing coating has a Pilling Bedworth ratio suitable for the formation of a low number of grain boundaries and a low number of gaps. In some embodiments, the Pilling Bedworth ratio of the base layer of the self-healing coating to the F-containing protective layer is about 0.5 to about 2. In some embodiments, the Pilling Bedworth ratio of the base layer of the self-healing coating to the F-containing protective layer is about between about 0.6 and about 2, between about 0.7 and about 2, between about 0.8 and about 2, between about 1 and about 2. In some embodiments, the Pilling Bedworth ratio of the base layer of the self-healing coating to the F-containing protective layer is 0.66, 0.93, 1.05, 1.10, 1.20, 1.30, 1.40, 1.50, 1.60, 1.70, 1.80, 1.90, 2, or any number in a range defined by these values. Table 1 shows the Pilling Bedworth Ratios of some reference metal oxides.

TABLE 1

| Metal | Metal oxide | Formula | R_{PB} |
|---|---|---|---|
| Potassium | Potassium oxide | K₂O | 0.474 |
| Sodium | Sodium oxide | Na₂O | 0.541 |
| Lithium | Lithium oxide | Li₂O | 0.567 |
| Strontium | Strontium oxide | SrO | 0.611 |
| Calcium | Calcium oxide | CaO | 0.64 |
| Barium | Barium oxide | BaO | 0.67 |
| Magnesium | Magnesium oxide | MgO | 0.81 |
| Aluminium | Aluminium oxide | Al₂O₃ | 1.28 |
| Lead | Lead(II) oxide | PbO | 1.28 |
| Platinum | Platinum(II) oxide | PtO | 1.56 |
| Zirconium | Zirconium(IV) oxide | ZrO₂ | 1.56 |
| Zinc | Zinc oxide | ZnO | 1.58 |
| Hafnium | Hafnium(IV) oxide | HfO₂ | 1.62 |
| Nickel | Nickel(II) oxide | NiO | 1.65 |
| Iron | Iron(II) oxide | FeO | 1.7 |
| Titanium | Titanium(IV) oxide | TiO₂ | 1.73 |
| Iron | Iron(II, III) oxide | Fe₃O₄ | 1.90 |
| Chromium | Chromium(III) oxide | Cr₂O₃ | 2.07 |
| Iron | Iron(III) oxide | Fe₂O₃ | 2.14 |
| Silicon | Silicon dioxide | SiO₂ | 2.15 |
| Tantalum | Tantalum(V) oxide | Ta₂O₅ | 2.47 |
| Niobium | Niobium pentoxide | Nb₂O₅ | 2.69 |
| Vanadium | Vanadium(V) oxide | V₂O₅ | 3.25 |
| Tungsten | Tungsten(VI) oxide | WO₃ | 3.3 |

In addition, the inventors have also discovered that other thermodynamic considerations may considered in order to form advantageous self-healing coatings. For instance, the formation energy of the AFₙ species may play an important role in the efficacy of self-healing coatings according to some embodiments of this disclosure. In some embodiments, the surface reaction may have a chemical equation of AₓB_{y}O_{z}(s)→AFₙ(s)+BF_{d}(g)+O₂(g). Without being limited by theory, the lower the formation energy, e.g., the energy associated with a chemical reaction, of the AFₙ species, the more effective formation of the self-healing coating may be. One possible explanation for this effect may be that the lower the formation energy of the AFₙ species, the more quickly the AFₙ species will be produced on surface of the self-healing coating. Quick and even production of the AFₙ species may reduce the number of gaps and grain boundaries present in the F-containing protective layer, e.g., the AFₙ species, which in turn may allow for limited diffusion of fluorine species further into the bulk of the self-healing coating. Table 2 shows the formation energy of AₓB_{y}O_{z} and AFₙ and the Pilling Bedworth ratios of some examples of self-healing coatings according to some embodiments. While the self-healing coatings in Table 2 show Pilling Bedworth ratios between about 0.66-1.05, they have relatively low formation energy associated with the formation of the corresponding AFₙ. As illustrated in Table 2, Al₂SiO₅, ZrSiO₄, HfSiO₄ and CaCO₃ may have a Pilling Bedworth ratios between about 0.66-1.05, the formation of corresponding AFₙ species has a relatively low formation energy, such that Al₂SiO₅, ZrSiO₄, HfSiO₄ and CaCO₃ may be used as the base layer of the self-healing coating.

TABLE 2

| | | AₓB_{y}O_{z} | | | | |
|---|---|---|---|---|---|---|
| | AₓB_{y}O_{z} | Formation | AFₙ | | | Pilling |
| | Crystal | Energy/ | Formation | V_{oxide} | V_{fluoride} | Bedworth |
| AₓB_{y}O_{z} | System | Atom | Energy/Atom | per A | per A | Ratio |
| Al₂SiO₅ | Orthorhombic | −3.39 | −3.89 | 44.10 | 46.16 | 1.05 |
| ZrSiO₄, | Tetragonal | −3.57 | −4.03 | 67.95 | 62.88 | 0.93 |
| HfSiO₄ | Tetragonal | −3.67 | −4.15 | 65.91 | 61.34 | 0.93 |
| CaCO₃ | Trigonal | −2.70 | −4.25 | 63.73 | 41.96 | 0.66 |

In some embodiments, the free energy of the AFₙ species is negative. In some embodiments, the free energy of the AFₙ species is less than −0.2 eV. In some embodiments, the free energy of the AFₙ species is between about −0.2 eV and about −4 eV. In some embodiments, the free energy of the AFₙ species is −2 eV, −2.4 eV, −2.6 eV, −2.8 eV, −3.2 eV, −3.4 eV, −3.8 eV, −4.0 eV, −4.6 eV, or a value in a range defined by any of these values.

As discussed above the general formula for the chemical reaction at the surface of the self-healing coating may be

$${A}_{x} {B}_{y} {O}_{z} ( s ) + m {H}_{e} {F}_{g} ( g ) \to {xAF}_{n} ( s ) + {yBF}_{d} ( g ) + \frac{e}{2} {H}_{2} O ( g ) + \frac{( z - e )}{2} {O}_{2} ( g ) .$$

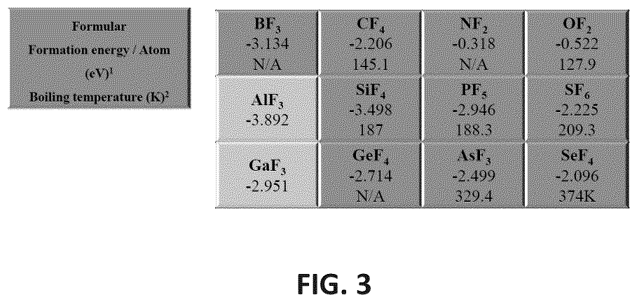

The inventors have also discovered that negative formation energies of the BF_{d} gaseous species may be advantageous in the production of self-healing coatings. FIG. 3 illustrates some examples of formation energies for the BF_{d} gaseous species. Without being limited by theory, the lower the formation energy, e.g., the energy associated with a chemical reaction, of the BF_{d} species, the more effective formation of the self-healing coating may be. One possible explanation for this effect may be that the lower the formation energy of the BF_{d} species, the faster and more likely the chemical reaction is to occur. If the chemical reaction prefers to quickly form BF_{d} species, then it will also form more corresponding AFₙ species more quickly on the self-healing coating. Quick and even production of the AFₙ species may reduce the number of gaps and grain boundaries present in the F-containing protective layer, which in turn can suppress diffusion of fluorine species further into the bulk of the self-healing coating.

In some embodiments, the free energy of the BF_{d} species is negative. In some embodiments, the free energy of the BF_{d} species is less than −0.2 eV. In some embodiments, the free energy of the BF_{d} species is between about −0.2 eV and about −4 eV. In some embodiments, the free energy of the BF_{d} species is −2 eV, −2.2 eV, −2.4 eV, −2.6 eV, −2.8 eV, −3 eV, −3.4 eV, −3.6 eV, −4 eV, or a value in a range defined by any of these values.

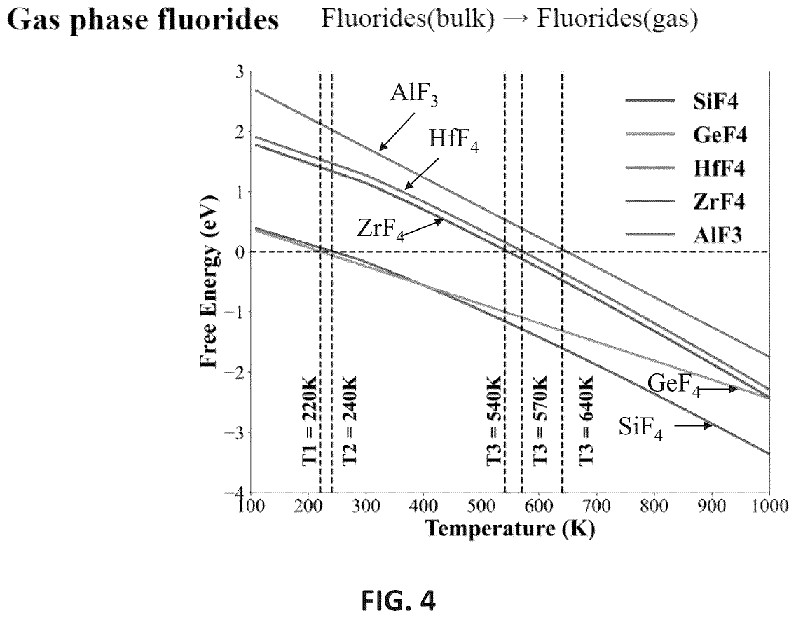

FIG. 4 illustrates some examples of free energy curves for the formation of the BF_{d} gaseous species. The free energy of a chemical reaction is a measure of the spontaneity of the chemical reaction. If the free energy of a chemical reaction is above 0, then the chemical reaction will not be spontaneous. If the free energy of a chemical reaction is below 0, then the chemical reaction will be spontaneous. In general, as temperature increases, the free energy of a chemical reaction decreases. FIG. 4 illustrates the effect of increased temperature on the free energy of the formation of the BF_{d} gaseous species. As the temperature increases, the free energy of the

$${A}_{x} {B}_{y} {O}_{z} ( s ) + m {H}_{e} {F}_{g} ( g ) \to {xAF}_{n} ( s ) + {yBF}_{d} ( g ) + \frac{e}{2} {H}_{2} O ( g ) + \frac{( z - e )}{2} {O}_{2} ( g )$$

general reaction decreases, such that the general reaction occurs more easily.

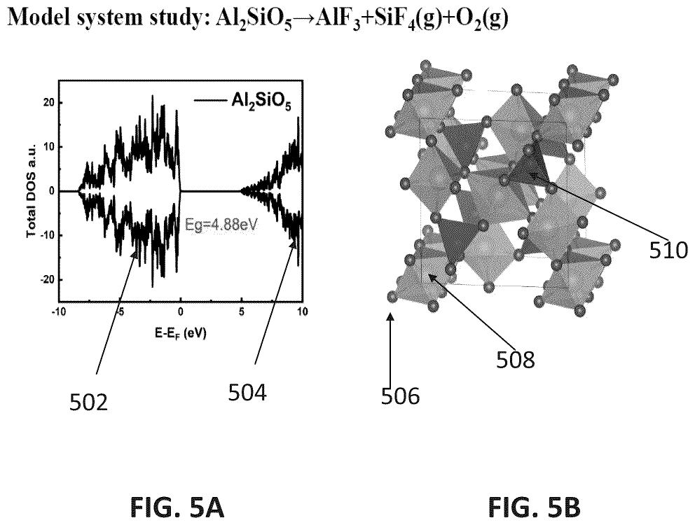

FIGS. 5A-5B illustrate the electronic and crystalline structure of one example of a self-healing coating material, Al₂SiO₅. FIG. 5A illustrates a density of states (DOS) as a function of a difference between an energy of a state (E) and a Fermi energy (E_{f}) of the material. The material Al₂SiO₅ is an insulator because the difference in energy between the valence band 502 and the conductive band 504 is significantly high. In Al₂SiO₅ the difference in this energy, e.g., the band gap, is 4.88 eV. FIG. 5B illustrates the crystalline structure of Al₂SiO₅. The crystalline structure of Al₂SiO₅ comprises oxygen atoms 506 which surround silicon atoms 508 and aluminum atoms 510. Al₂SiO₅ may have an orthorhombic andalusite crystal structure.

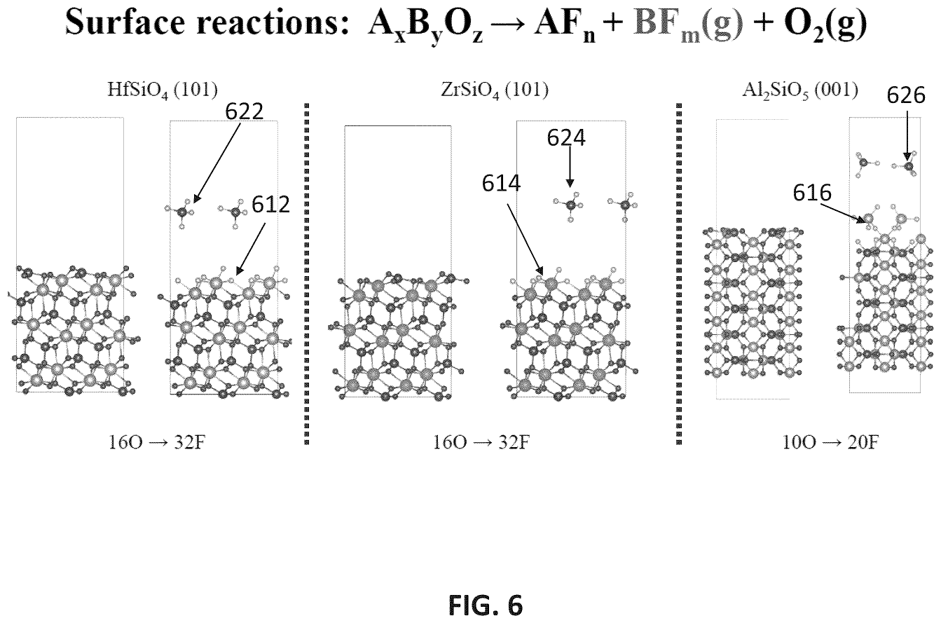

FIG. 6 illustrates surface reactions that may occur during the general reaction

$${A}_{x} {B}_{y} {O}_{z} ( s ) + m {H}_{e} {F}_{g} ( g ) \to {xAF}_{n} ( s ) + {yBF}_{d} ( g ) + \frac{e}{2} {H}_{2} O ( g ) + \frac{( z - e )}{2} {O}_{2} ( g )$$

according to some embodiments. The F-containing reactants react with the surfaces of the self-healing coatings, thereby creating an AFₙ surface layer and a BF_{d} gas. The BF_{d} gas may be removed from the system after formation. For example, as shown in FIG. 6, HfSiO₄ may be used as the base layer of the self-healing layer. HfSiO₄ may react with F-containing reactant to form a solid HfF₄ surface layer 612 and SiF₄ gas 622. The SiF₄ gas 622 may be removed from the surface easily. In another example, as shown in FIG. 6, ZrSiO₄ may be used as the base layer of the self-healing layer. ZrSiO₄ may react with F-containing reactant to form a solid ZrF₄ surface layer 614 and SiF₄ gas 624. The SiF₄ gas 624 may be removed from the surface easily. In another example, as shown in FIG. 6, Al₂SiO₅ may be used as the base layer of the self-healing layer. Al₂SiO₅ may react with F-containing reactant to form a solid AlF₃ surface layer 616 and SiF₄ gas 626. The SiF₄ gas 626 may be removed from the surface easily.

Table 3 illustrates the free energy of examples of the general reaction

$${A}_{x} {B}_{y} {O}_{z} ( s ) + m {H}_{e} {F}_{g} ( g ) \to {xAF}_{n} ( s ) + {yBF}_{d} ( g ) + \frac{e}{2} {H}_{2} O ( g ) + \frac{( z - e )}{2} {O}_{2} ( g )$$

according to some embodiments. In these examples, the F-containing gaseous element HₑF_{g}(g) is hydrofluoric acid HF.

TABLE 3

| | | ΔE per HF |
|---|---|---|
| Reactions | ΔE (eV) | (eV) |
| Al₂SiO₅(b) + 10 HF(g) = 2AlF₃(g) + SiF₄(g) + 5H₂O (g) | 0.16 | 0.02 |
| HfSiO₄(b) + 8 HF(g) = HfF₄(g) + SiF₄(g) + 4H₂O(g) | −1.21 | −0.15 |
| ZrSiO₄(b) + 8 HF(g) = ZrF₄(g) + SiF₄(g) + 4H₂O(g) | −1.53 | −0.19 |
| Al₂SiO₅(surf) + 12 HF(g) = AlSixFy(surf) + 6H₂O (g) | −10.47 | −0.87 |
| Al₂SiO₅(surf) + 16 HF(g) = 4AlFₓ(surf) + 2SiF₄(g) + 8H₂O (g) | −12.65 | −0.79 |
| Al₂SiO₅(surf) + 20 HF(g) = 4AlF₃(surf) + 2SiF₄(g) + 10H₂O (g) | −13.45 | −0.67 |
| HfSiO₄(surf) + 32 HF(g) = 4HfF₄(surf) + 4SiF₄(g) + 16H₂O(g) | −27.41 | −0.86 |
| ZrSiO₄(surf) + 32 HF(g) = 4ZrF₄(surf) + 4SiF₄(g) + 16H₂O(g) | −27.01 | −0.84 |

As illustrated in Table 3, the reactions between each the surface layer of Al₂SiO₅(surf), HfSiO₄(surf) and ZrSiO₄(surf) and HF(g) have relatively large negative free energy, such that the reactions are thermodynamically favorable and occur spontaneously. In addition, the reactions between each of the bulk of Al₂SiO₅(b), HfSiO₄(b) and ZrSiO₄(b) and HF(g) has a relatively small negative free energy or a positive free energy, such that the reactions may stop once the surface layer of AₓB_{y}O_{z} is converted to corresponding AFₙ. In some embodiments, the HF used in these reactions may be a byproduct of other reactions that occur before the general reaction. For instance, in a deposition reactor system, HF may be a by-product of a chemical vapor deposition reaction.

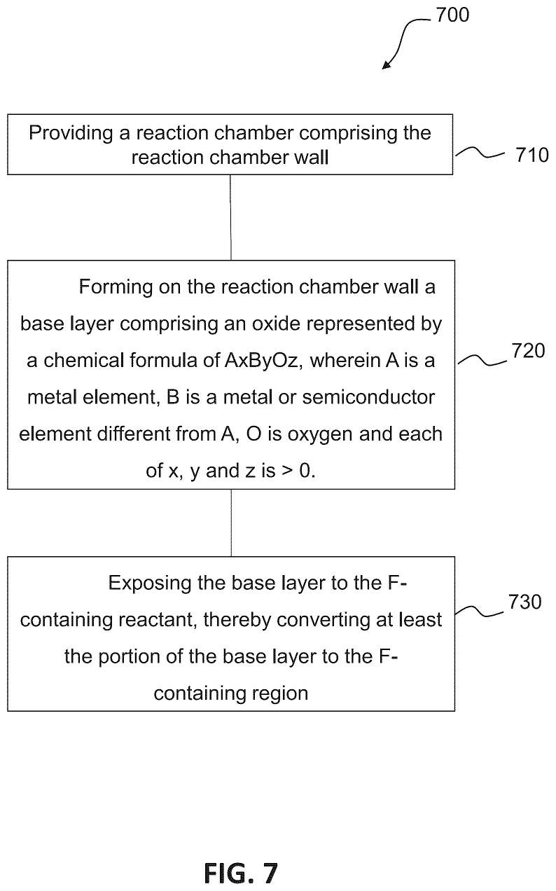

FIG. 7 is a flow chart schematically illustrating a method 700 for forming a protective coating on a reaction chamber wall. Referring to FIG. 7, the method 700 includes providing 710 a reaction chamber comprising the reaction chamber wall. In some embodiments, providing 710 may occur prior to a first use of the vapor deposition system, e.g., ex-situ, or during or after a deposition process, e.g., in situ. The method 700 may additionally comprise forming 720 on the reaction chamber wall a base layer comprising an oxide represented by a chemical formula of AₓB_{y}O_{z}, wherein A is a metal element, B is a metal or semiconductor element different from A, O is oxygen and each of x, y and z is >0. This protective coating may be configured such that upon exposure to a F-containing reactant, at least a portion of the base layer reacts with the fluorine (F)-containing reactant and is converted to a F-containing region comprising a solid fluoride of the A. The protective coating may be a self-healing coating described in some of the embodiments above. In some embodiments, forming 720 may comprise lining the reaction chamber wall of a vapor deposition system with a base layer. In some embodiments, lining the reaction chamber wall may occur prior to a first use of the reaction chamber to process a semiconductor substrate. The method 700 may further comprise a later stage, including exposing 730 the base layer to the F-containing reactant, thereby converting the at least a portion of the base layer to the F-containing region. As discussed in other embodiments above, exposing 730 the first layer with a fluorine reactant may form a AFₙ region or layer on the surface of the base layer. As discussed above, this AFₙ region or layer may have advantageous properties, e.g., it may inhibit the diffusion of fluorine to the base layer and may protect portions of the surface from corrosion caused by fluorine reactants. In some embodiments, exposing 730 the base layer with a F-containing reactant may occur in situ, e.g., during a vapor deposition process on a semiconductor substrate, or ex situ, e.g., prior to a first vapor deposition process on a semiconductor substrate. When exposing 730 occurs in situ, the F-containing reactant may be a by-product of a vapor deposition process within the reaction chamber. In some embodiments, the F-containing reactant is not a by-product of a vapor deposition process.

### EXAMPLE EMBODIMENTS

1. A protective coating formed on a reaction chamber wall, the protective coating comprising:
a base layer comprising an oxide represented by a chemical formula of AₓB_{y}O_{z},
wherein A is a metal element, B is a metal or semiconductor element different from A, O is oxygen and each of x, y and z is above 0, and
wherein the protective coating is configured such that upon exposure to a fluorine (F)-containing reactant, at least a portion of the base layer reacts with the F-containing reactant and is converted to a F-containing region comprising a solid fluoride of the A.

2. The protective coating of Embodiment 1, wherein a Pilling Bedworth ratio (R) of the element A is between 0.5 and 2, wherein the R is defined as:

$$R = \frac{{n}_{1} {V}_{fluoride}}{{n}_{2} {V}_{oxide}}$$

wherein n₁ and n₂ respectively represent numbers of moles of the A in the solid fluoride and the oxide in a balanced chemical reaction equation converting the oxide to the solid fluoride, and V_{fluoride} and V_{oxide} respectively represent volumes of the solid fluoride and the oxide.

3. The protective coating of any one of the above Embodiments, wherein the R of the element A is about 0.9 to 2.

4. The protective coating of any one of the above Embodiments, wherein the A comprises one or more of aluminum (Al), hafnium (Hf), zirconium (Zr), calcium (Ca) and a rare earth element.

5. The protective coating of any one of the above Embodiments, wherein the base layer comprises one or more of HfSiO₄, ZrSiO₄, Al₂SiO₅, and CaCO₃.

6. The protective coating of any one of the Embodiments, wherein the F-containing region has a chemical formula of AFₙ, wherein the A is the metal, F is fluorine, and n>0.

7. The protective coating of Embodiment 6, wherein the F-containing region comprises one or more of HfF₄, ZrF₄, CaF₂, and AlF₃.

8. The protective coating of any one of the above Embodiments, wherein upon exposure to the fluorine-containing reactant, the at least a portion of the base layer reacts with the F-containing reactant and is converted to the F-containing region comprising the solid fluoride of the A and a volatile fluoride of the B.

9. The protective coating of any one of the above Embodiments, wherein upon exposure to a F-containing reactant, the at least a portion of the base layer reacts with the F-containing reactant and is converted to the F-containing region comprising the solid fluoride of the A and a volatile fluoride of the B in a chemical reaction accompanied by a negative change in free energy.

10. The protective coating of Embodiment 8, wherein the volatile fluoride of the B has a chemical formula of BFₙ, where F is fluorine, and n>0.

11. The protective coating of Embodiment 10, wherein the volatile fluoride of the B comprises one or more of SiF₄, CF₄, and GeF₄.

12. The protective coating of any one of the above Embodiments, wherein a thickness of the F-containing region is greater than about 5 μm.

13. The protective coating of any one of the above Embodiments, wherein a thickness of the F-containing region is less than about 5 μm.

14. The protective coating of any one of the above Embodiments, wherein a thickness of the F-containing region is between about 1 μm and about 100 μm.

15. The protective coating of any one of the above Embodiments, wherein the F-containing reactant comprises HF, F₂, a fluorocarbon, a hydrofluorocarbon or combinations thereof.

16. The protective coating of Any one of the above Embodiments, wherein the conversion of the base layer to the F-containing region stops when the F-containing region reaches a self-limiting thickness.

17. The protective coating of Embodiment 16, wherein the self-limiting thickness is about 5 μm.

18. The protective coating of Any one of the above Embodiments, wherein the protective coating is formed on the reaction chamber wall of a semiconductor processing chamber configured to flow a F-containing gas thereinto.

19. The protective coating of Embodiment 18, wherein the semiconductor processing chamber has processed at least one semiconductor substrate, and wherein incorporation of at least some of F atoms of the F-containing region is caused by the processing of the at least one semiconductor substrate.

20. A semiconductor reaction chamber comprising the reaction chamber wall having the protective coating according to any one of the above Embodiments.

21. The semiconductor reaction chamber of Embodiment 20, wherein the reaction chamber is an atomic layer deposition reaction chamber.

22. A protective coating formed on a reaction chamber wall, the protective coating comprising:
a base layer comprising an oxide represented by a chemical formula of AₓB_{y}O_{z}, wherein A is a metal element, B is a metal or semiconductor element different from A, O is oxygen and each of x, y and z is >0; and
a fluorine (F)-containing region comprising a solid fluoride of the A formed over the base layer.

23. The protective coating of Embodiment 22, wherein at least a portion of the base layer is configured to react with a F-containing reactant to form the F-containing region comprising the solid fluoride of the A upon exposure to the F-containing reactant.

24. The protective coating of Embodiment 23, wherein the F-containing reactant comprises HF, F₂, a fluorocarbon, a hydrofluorocarbon or combinations thereof.

25. The protective coating of Embodiment 23 or 24, wherein the exposure of the base layer to the F-containing reactant comprises removing the F-containing region above the base layer.

26. The protective coating of Embodiment 25, wherein removing the F-containing region comprises scratching the F-containing region.

27. The protective coating of any one of Embodiments 23-26, wherein upon exposure to the F-containing reactant, the at least a portion of the base layer reacts with the F-containing reactant and is converted to the F-containing region comprising the solid fluoride of the A and a volatile fluoride of the B.

28. The protective coating of any one of Embodiments 23-27, wherein upon exposure to a F-containing reactant, the at least a portion of the base layer reacts with the F-containing reactant and is converted to the F-containing region comprising the solid fluoride of the A and a volatile fluoride of the B in a chemical reaction accompanied by a negative change in free energy.

29. The protective coating of Embodiment 27, wherein the volatile fluoride of the B has a chemical formula of BFₙ, where F is fluorine, and n>0.

30. The protective coating of Embodiment 27 or 28, wherein the volatile fluoride of the B comprises one or more of SiF₄, CF₄, and GeF₄.

31. The protective coating of any one of Embodiments 23-30, wherein the formation of the solid fluoride of the A stops when the F-containing region reaches a self-limiting thickness.

32. The protective coating of Embodiment 31, wherein the self-limiting thickness is about 5 μm.

33. The protective coating of any one of Embodiments 22-32, wherein a Pilling Bedworth ratio (R) of the element A is between 0.5 and 2, wherein the R is defined as:

$$R = \frac{{n}_{1} {V}_{fluoride}}{{n}_{2} {V}_{oxide}}$$

wherein n₁ and n₂ respectively represent numbers of moles of the A in the solid fluoride and the oxide in a balanced chemical reaction equation converting the oxide to the solid fluoride, and V_{fluoride} and V_{oxide} respectively represent volumes of the solid fluoride and the oxide.

34. The protective coating of Embodiment 33, wherein the R of the element A is about 0.9 to 2.

35. The protective coating of any one of Embodiments 22-34, wherein the A comprises one or more of aluminum (Al), hafnium (Hf), zirconium (Zr), calcium (Ca) and a rare earth element.

36. The protective coating of any one of Embodiments 22-35, wherein the base layer comprises one or more of HfSiO₄, ZrSiO₄, Al₂SiO₅, and CaCO₃.

37. The protective coating of any one of Embodiments 22-36, wherein the F-containing region has a chemical formula of AFₙ, wherein the A is the metal, F is fluorine, and n>0.

38. The protective coating of any one of Embodiments 22-37, wherein the F-containing region comprises one or more of HfF₄, ZrF₄, CaF₂, and AlF₃.

39. The protective coating of any one of Embodiments 22-38, wherein a thickness of the F-containing region is greater than about 5 μm.

40. The protective coating of any one of Embodiments 22-39, wherein a thickness of the F-containing region is less than about 5 μm.

41. The protective coating of any one of Embodiments 22-40, wherein a thickness of the F-containing region is between about 1 μm and about 100 μm.

42. The protective coating of any one of Embodiments 22-41, wherein the protective coating is formed on the reaction chamber wall of a semiconductor processing chamber configured to flow a F-containing gas thereinto.

43. The protective coating of Embodiment 42, wherein the semiconductor processing chamber has processed at least one semiconductor substrate, and wherein incorporation of at least some of F atoms of the F-containing region is caused by the processing of the at least one semiconductor substrate.

44. A semiconductor reaction chamber comprising the reaction chamber wall having the protective coating according to any one of Embodiments 22-43.

45. The semiconductor reaction chamber of Embodiment 44, wherein the reaction chamber is an atomic layer deposition reaction chamber.

46. A method of forming a protective coating on a reaction chamber wall:
providing a reaction chamber comprising the reaction chamber wall; and
forming on the reaction chamber wall a base layer comprising an oxide represented by a chemical formula of AₓB_{y}O_{z}, wherein A is a metal element, B is a metal or semiconductor element different from A, O is oxygen and each of x, y and z is >0,
wherein the protective coating is configured such that upon exposure to a fluorine (F)-containing reactant, at least a portion of the base layer reacts with the F-containing reactant and is converted to a F-containing region comprising a solid fluoride of the A.

47. The method of Embodiment 46, further comprising exposing the base layer to the F-containing reactant, thereby converting at least the portion of the base layer to the F-containing region.

48. The method of Embodiment 46 or 47, wherein providing the base layer comprises lining the reaction chamber wall of a vapor deposition system with the base layer.

49. The method of any one of Embodiments 46-48, wherein at least lining the reaction chamber wall occurs prior to a first use of a reaction chamber to process a semiconductor substrate.

50. The method of any one of Embodiments 46-49, wherein exposing the base layer with the F-containing reactant occurs in situ during a vapor deposition process on a semiconductor substrate.

51. The method of any one of Embodiments 46-50, wherein the F-containing reactant is a by-product of a vapor deposition process within the reaction chamber.

52. The method of any one of Embodiments 46-51, wherein the F-containing reactant is not a by-product of a vapor deposition process within the reaction chamber.

53. The method of any one of Embodiments 46-51, wherein the protective coating is in accordance with any one of Embodiments 1-45.

Such simple modifications and improvements of the various embodiments disclosed herein are within the scope of the disclosed technology, and the specific scope of the disclosed technology will be additionally defined by the appended claims.

In the foregoing, it will be appreciated that any feature of any one of the embodiments can be combined or substituted with any other feature of any other one of the embodiments.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or whether these features, elements and/or states are included or are to be performed in any particular embodiment.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately,” “about,” “generally,” and “substantially” may refer to an amount that is within less than 10% of, within less than 5% of, within less than 1% of, within less than 0.1% of, and within less than 0.01% of the stated amount, depending on the desired function or desired result.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while features are presented in a given arrangement, alternative embodiments may perform similar functionalities with different components and/or sensor topologies, and some features may be deleted, moved, added, subdivided, combined, and/or modified. Each of these features may be implemented in a variety of different ways. Any suitable combination of the elements and acts of the various embodiments described above can be combined to provide further embodiments. The various features and processes described above may be implemented independently of one another, or may be combined in various ways. All possible combinations and subcombinations of features of this disclosure are intended to fall within the scope of this disclosure.

1. A protective coating formed on a reaction chamber wall, the protective coating comprising:
a base layer comprising an oxide represented by a chemical formula of AₓB_{y}O_{z},
wherein A is a metal element, B is a metal or semiconductor element different from the A, O is oxygen and each of x, y and z is greater than 0, and
wherein the protective coating is configured such that upon exposure to a fluorine (F)-containing reactant, at least a portion of the base layer reacts with the F-containing reactant and is converted to a F-containing region comprising a solid fluoride of the A.

2. The protective coating of claim 1, wherein a Pilling Bedworth ratio (R) of the A is between 0.5 and 2, wherein the R is defined as:
$$R = \frac{{n}_{1} {V}_{fluoride}}{{n}_{2} {V}_{oxide}}$$
wherein n and n₂ respectively represent numbers of moles of the A in the solid fluoride and the oxide in a balanced chemical reaction equation converting the oxide to the solid fluoride, and V_{fluoride} and V_{oxide} respectively represent volumes of the solid fluoride and the oxide.

3. The protective coating of claim 2, wherein the R of the element A is about 0.9 to 2.

4. The protective coating of claim 1, wherein the A comprises one or more of aluminum (Al), hafnium (Hf), zirconium (Zr), calcium (Ca) and a rare earth element.

5. The protective coating of claim 1, wherein the base layer comprises one or more of HfSiO₄, ZrSiO₄, Al₂SiO₅, and CaCO₃.

6. The protective coating of claim 1, wherein the F-containing region has a chemical formula of AFₙ, wherein the A is the metal element, F is fluorine, and n>0.

7. The protective coating of claim 6, wherein the F-containing region comprises one or more of HfF₄, ZrF₄, CaF₂, and AlF₃.

8. The protective coating of claim 1, wherein upon exposure to the fluorine-containing reactant, the at least a portion of the base layer reacts with the F-containing reactant and is converted to the F-containing region comprising the solid fluoride of the A and a volatile fluoride of the B.

9. The protective coating of claim 1, wherein upon exposure to the F-containing reactant, the at least a portion of the base layer reacts with the F-containing reactant and is converted to the F-containing region comprising the solid fluoride of the A and a volatile fluoride of the B in a chemical reaction accompanied by a negative change in free energy.

10. The protective coating of claim 8, wherein the volatile fluoride of the B has a chemical formula of BFₘ, where F is fluorine, and m>0.

11. The protective coating of claim 10, wherein the volatile fluoride of the B comprises one or more of SiF₄, CF₄ and GeF₄.

12. (canceled)

13. (canceled)

14. The protective coating of claim 1, wherein a thickness of the F-containing region is between about 1 μm and about 100 μm.

15. The protective coating of claim 1, wherein the F-containing reactant comprises HF, F₂, a fluorocarbon, a hydrofluorocarbon or combinations thereof.

16. The protective coating of claim 1, wherein the conversion of the base layer to the F-containing region stops when the F-containing region reaches a self-limiting thickness.

17. The protective coating of claim 16, wherein the self-limiting thickness is about 5 μm.

18. The protective coating of claim 1, wherein the protective coating is formed on the reaction chamber wall of a semiconductor processing chamber configured to flow a F-containing gas thereinto.

19. The protective coating of claim 18, wherein the semiconductor processing chamber has processed at least one semiconductor substrate, and wherein incorporation of at least some of F atoms of the F-containing region is caused by the processing of the at least one semiconductor substrate.

20. A semiconductor reaction chamber comprising the reaction chamber wall having the protective coating according to claim 1.

21. The semiconductor reaction chamber of claim 20, wherein the reaction chamber is an atomic layer deposition reaction chamber.

22. A protective coating formed on a reaction chamber wall, the protective coating comprising:
a base layer comprising an oxide represented by a chemical formula of AₓB_{y}O_{z}, wherein A is a metal element, B is a metal or semiconductor element different from the A, O is oxygen and each of x, y and z is >0; and
a fluorine (F)-containing region comprising a solid fluoride of the A formed over the base layer.

23. The protective coating of claim 22, wherein at least a portion of the base layer is configured to react with a F-containing reactant to form the F-containing region comprising the solid fluoride of the A upon exposure to the F-containing reactant.

24. (canceled)

25. The protective coating of claim 23, wherein the exposure of the base layer to the F-containing reactant comprises removing the F-containing region above the base layer.

26-52. (canceled)
